(19) United States
(12) Patent Application Publication
(10) Pub. No.: US 2011/0215356 A1
(43) Pub. Date: Sep. 8, 2011

(54) LIGHT EMITTING ELEMENT, LIGHT EMITTING DEVICE, AND METHOD FOR MANUFACTURING LIGHT EMITTING ELEMENT

(75) Inventors: Masaaki OGAWA, Kanagawa-ken (JP); Yasuhisa OHMURO, Tokyo (JP)

(73) Assignee: Kabushiki Kaisha Toshiba, Tokyo (JP)

(21) Appl. No.: 12/976,730

(22) Filed: Dec. 22, 2010

(30) Foreign Application Priority Data
Mar. 2, 2010 (JP) 2010-045830

(51) Int. Cl. H01L 33/20; H01L 33/62

(52) U.S. Cl. 257/98; 438/29; 257/E33.074

(57) ABSTRACT

According to embodiment, a light emitting element includes a light emitting layer having a first major surface and a second major surface, a first electrode provided on the first major surface side of the light emitting layer, and a second electrode provided on the second major surface side of the light emitting layer and having a basic outline. Furthermore, the light emitting element includes a current blocking portion provided between the first electrode and the light emitting layer or between the second electrode and the light emitting layer, and has an outline with a protrusion-depression pattern with respect to a virtual outline similar in shape to the basic outline of the second electrode.

### CROSS-REFERENCE TO RELATED APPLICATIONS

This application is based upon and claims the benefit of priority from the prior Japanese Patent Application No. 2010-45830, filed on Mar. 2, 2010; the entire contents of which are incorporated herein by reference.

### FIELD

Embodiments described herein generally to a light emitting element, and a method for manufacturing a light emitting element.

### BACKGROUND

Light emitting elements such as LED (light emitting diode) are widely used in full-color displays, traffic and signal equipment, vehicle-mounted applications, and so on. Thus, there is demand for light emitting elements with higher light emission intensity. In such light emitting elements, for instance, a light emitting layer is provided between cladding layers. Electrons are injected into the light emitting layer from an N-side electrode, and holes are injected into the light emitting layer from a P-side electrode. Light emission occurs by recombination of electrons and holes at a PN junction interface formed in the light emitting layer.

Examples of the electrode structure, for injecting electrons and holes into the light emitting layer, include a structure with the N-side electrode and P-side electrode both formed on the same side of the light emitting layer, and include a vertical electrode structure with the electrodes formed above and below the light emitting layer. Recently, as for light emitting elements of the vertical electrode structure, a structure for light emission with higher brightness has been proposed. In this structure, a current blocking layer is provided between the upper and lower electrode so that the path of the current flowing between the upper and lower electrode lies outside the upper electrode (e.g., refer to JP-A-2004-356137 (Kokai)).

However, if a current blocking layer is provided between the upper and lower electrode, light emission concentrates on the neighborhood of the outer periphery of the upper electrode, or the neighborhood of the outer periphery of the current blocking layer. That is, light emission is obtained only from a limited portion of the light emitting layer such as the vicinity of the outer periphery of the upper electrode or the vicinity of the outer periphery of the current blocking layer. Thus, unfortunately, the increase of light emission intensity is limited.

### BRIEF DESCRIPTION OF THE DRAWINGS

FIGS. 1A and 1B are schematic views of a relevant part of a light emitting element according to a first embodiment. FIG. 1A is a schematic plan view of the relevant part, and FIG. 1B is a schematic sectional view of the relevant part;

FIGS. 2A to 2C show schematic views of a relevant part of a light emitting element according to a comparative example, and the light intensity distribution thereof. FIG. 2A is a schematic plan view of the relevant part, FIG. 2B is a schematic sectional view of the relevant part, and FIG. 2C illustrates the light intensity distribution;

FIGS. 3A to 3C illustrate patterns of the current blocking portion. FIG. 3A shows a first pattern, FIG. 3B shows a second pattern, and FIG. 3C shows a third pattern;

FIGS. 4A and 4B illustrate a process for forming the third pattern. FIG. 4A shows a first stage of pattern formation, and FIG. 4B shows a second stage of pattern formation;

FIGS. 5A and 5B illustrate light emission intensity and forward voltage. FIG. 5A illustrates the relationship between the first to third pattern and light emission intensity. FIG. 5B illustrates the relationship between the first to third pattern and forward voltage;

FIGS. 6A to 6C show variations of the current blocking portion according to the first embodiment. FIG. 6A is a plan view of the current blocking portion of a first variation. FIG. 6B is a plan view of the current blocking portion of a second variation. FIG. 6C is a plan view of the current blocking portion of a third variation;

FIGS. 7A and 7B show other variations of the current blocking portion according to the first embodiment. FIG. 7A is a plan view of the current blocking portion of a fourth variation. FIG. 7B is a plan view of the current blocking portion of a fifth variation;

FIGS. 8A and 8B are schematic views of a relevant part of a light emitting element according to a second embodiment. FIG. 8A is a schematic plan view of the relevant part, and FIG. 8B is a schematic sectional view of the relevant part;

FIGS. 9A and 9B are schematic views of a relevant part of a light emitting element according to a third embodiment. FIG. 9A is a schematic plan view of the relevant part, and FIG. 9B is a schematic sectional view of the relevant part;

FIGS. 10A and 10B are schematic views of a relevant part of a light emitting element according to a fourth embodiment. FIG. 10A is a schematic plan view of the relevant part of the light emitting element, and FIG. 10B is a schematic sectional view of the relevant part;

FIGS. 11A and 11B are schematic views of a relevant part of a light emitting element according to a fifth embodiment. FIG. 11A is a schematic plan view of the relevant part, and FIG. 11B is a schematic sectional view of the relevant part;

FIGS. 12A and 12B are schematic views of a relevant part of a light emitting element according to a sixth embodiment. FIG. 12A is a schematic plan view of the relevant part, and FIG. 12B is a schematic sectional view of the relevant part;

FIG. 13 is a schematic sectional view of a relevant part of a light emitting device according to a seventh embodiment;

FIGS. 14A and 14B are schematic sectional views of the relevant part illustrating a process for manufacturing the light emitting element. FIG. 14A shows the step of forming a semiconductor stacked body, and FIG. 14B shows the step of forming a mask membrane;

FIGS. 15A to 15C are schematic sectional views of the relevant part illustrating the process for manufacturing the light emitting element. FIG. 15A shows the step of forming a current blocking portion, FIG. 15B shows the step of forming a reflective film, and FIG. 15C shows the step of forming a semiconductor layer.

### DETAILED DESCRIPTION

In general, according to one embodiment, a light emitting element includes a light emitting layer having a first major surface and a second major surface, a first electrode provided on the first major surface side of the light emitting layer, and a second electrode provided on the second major surface side of the light emitting layer and having a basic outline. Furthermore, the light emitting element includes a current blocking portion provided between the first electrode and the light emitting layer or between the second electrode and the light emitting layer, and has an outline with a protrusion-depression pattern with respect to a virtual outline similar in shape to the basic outline of the second electrode.

According to another embodiment, a light emitting device includes an enclosure, the light emitting element provided in the enclosure, a resin layer provided so as to cover the light emitting element, a first lead frame electrically connected to the first electrode of the light emitting element, and a second lead frame electrically connected to the second electrode of the light emitting element.

According to another embodiment, a method for manufacturing a light emitting element includes forming a semiconductor stacked body including a light emitting layer on upper side of a semiconductor substrate; and forming a current blocking portion on upper side of the semiconductor stacked body. The current blocking portion has an outline with a protrusion-depression pattern with respect to a virtual outline similar in shape to a basic outline of an electrode provided on a second major surface side opposite to a first major surface side of the light emitting layer.

Embodiments will now be described with reference to the drawings.

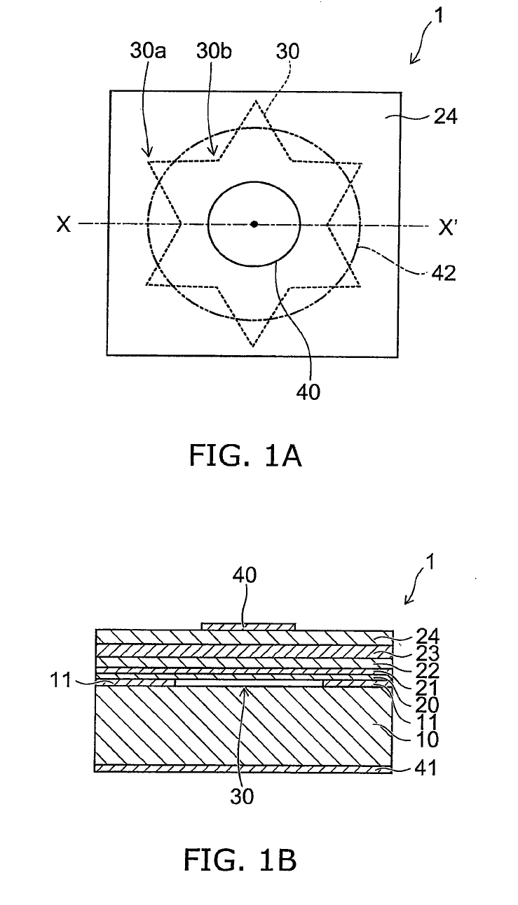

FIGS. 1A and 1B are schematic views of a relevant part of a light emitting element according to a first embodiment. FIG. 1A is a schematic plan view of the relevant part, and FIG. 1B is a schematic sectional view of the relevant part. FIG. 1B shows an X-X′ cross section of FIG. 1A.

The light emitting element 1 according to the first embodiment includes a stacked body of semiconductor layers. For instance, the stacked body includes a semiconductor layer 10, a first cladding layer 21 provided above the semiconductor layer 10, a light emitting layer 22 provided above the first cladding layer 21, a second cladding layer 23 provided above the light emitting layer 22, and a current diffusion layer 24 provided above the second cladding layer 23. A current blocking portion 30 is provided between the semiconductor layer 10 and the light emitting layer 22.

The light emitting element 1 has a vertical electrode structure including an upper electrode 40 and a lower electrode 41. For instance, the lower electrode 41 as a first electrode is provided on the lower side of the semiconductor layer 10, and the upper electrode 40 as a second electrode is provided above the current diffusion layer 24. The current diffusion layer 24 is provided immediately below the upper electrode 40.

In the light emitting element 1 of this example, for instance, a reflective film 11 is provided on the upper side of the semiconductor layer 10 such as a silicon substrate. For instance, the current blocking portion 30 may be provided in the reflective film 11. The current blocking portion 30 may be an insulating layer, or space. Above the reflective film 11, a P-type GaAs (gallium arsenide) buffer layer 20, a P-type cladding layer 21, a light emitting layer 22, an N-type cladding layer 23, and an N-type current diffusion layer 24 are sequentially stacked. Above the current diffusion layer 24, an N-side upper electrode 40 is provided. The planar shape of the upper electrode 40 is circular, for instance. One side of the light emitting element 1 (one side in FIG. 1A) has a length of e.g. 300 μm. Then, the upper electrode 40 has a diameter of e.g. 100 μm. In this configuration, the area of the upper electrode 40 is smaller than the area of the current diffusion layer 24. Furthermore, a P-side lower electrode 41 is provided on the lower side of the semiconductor layer 10.

Thus, the light emitting element 1 has a vertical electrode structure with the light emitting layer 22 provided between the upper electrode 40 and the lower electrode 41. In other words, if the lower surface of the light emitting layer 22 is referred to as a first major surface, and the upper surface of the light emitting layer 22 is referred to as a second major surface, then the lower electrode 41 as a first electrode is provided on the first major surface side (lower surface side) of the light emitting layer 22, and the upper electrode 40 as a second electrode is provided on the second major surface side (upper surface side) of the light emitting layer 22.

As viewed in the direction perpendicular to the major surface of the semiconductor layer 10, the current blocking portion 30 has a shape including a plurality of protrusions 30a and a plurality of depressions 30b. The periphery of the current blocking portion 30 directs from the center of the current blocking portion 30 to outside at the plurality of protrusions 30a. The periphery of the current blocking portion 30 directs from outside to inside at the plurality of depressions 30b.

For instance, with reference to a similar shape 42 having a larger area than the upper electrode 40, the protrusion 30a is directed (projected) outward from this reference, and the depression 30b is directed (depressed) inward from this outer periphery. That is, if the outline of the upper electrode 40 is referred to as a basic outline, the current blocking portion 30 has a protrusion-depression pattern with respect to a virtual outline that is a similar shape 42 to the basic outline of the upper electrode 40. The basic outline of the upper electrode 40 includes no protrusion or depression, but has a circular periphery. As viewed in the direction perpendicular to the second major surface (upper surface side) of the light emitting layer 22, the periphery of the current blocking portion 30 protrudes outside the periphery of the upper electrode 40.

Next, the function and effect of the light emitting element 1 are described.

First, before describing the function and effect of the light emitting element 1, the function and effect of a light emitting element 100 according to a comparative example are described.

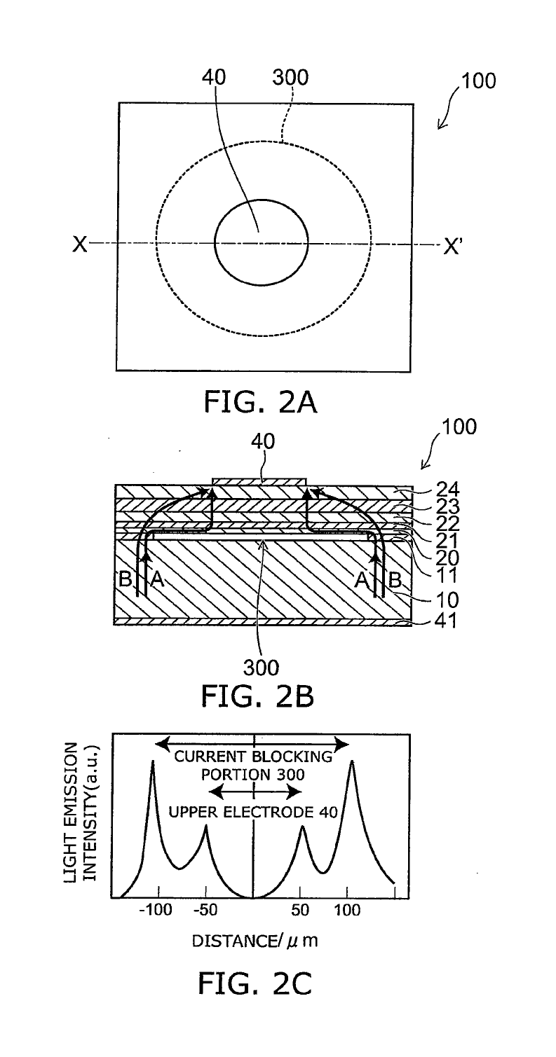

FIGS. 2A to 2C show schematic views of a relevant part of a light emitting element according to a comparative example, and the light intensity distribution thereof. FIG. 2A is a schematic plan view of the relevant part, FIG. 2B is a schematic sectional view of the relevant part, and FIG. 2C illustrates the light intensity distribution. FIG. 2B shows an X-X′ cross section of FIG. 2A.

The current blocking portion 300 of the light emitting element 100 according to the comparative example does not include the aforementioned protrusions 12a and depressions 12b. That is, the planar structure of the current blocking portion 300 of the light emitting element 100 has a circular shape similar to the upper electrode 40. The remaining structure is the same as that of the light emitting element 1. The diameter of the current blocking portion 300 is 180 μm.

The light emitting element 100 can be applied with a forward voltage that the lower electrode 41 is set at a positive potential and the upper electrode 40 is set at a negative potential or ground potential. Then, the light emitting layer 22 emits light by electron-hole recombination occurring at a PN junction in the light emitting layer 22. The light emitted from the light emitting layer 22 to the lower side of the light emitting element 100 is reflected by the reflective film 11 and directed to the upper side of the light emitting element 100.

The current diffusion layer 24 is a member for allowing the current flowing in the light emitting element 100 to uniformly diffuse in the horizontal plane, thereby enabling current injection in a wider area of the light emitting layer 22. However, when a voltage is applied between the lower electrode 41 and the upper electrode 40, the electric field concentrates on the periphery of the upper electrode 40 actually. Hence, a main current path is formed below the outer periphery of the upper electrode 40. The current flow of this main current path is blocked by the current blocking portion 300. The current flow is indicated by arrow A in the figure. On the other hand, the current blocking portion 300 is provided in the reflective film 11 made of metal. Hence, the electric field concentrates also on both ends of the current blocking portion 300. Thus, another main current path indicated by arrow B is also formed.

Hence, as shown in FIG. 2C, the light emission distribution of the light emitting element 100 is intense near the outer periphery of the upper electrode 40 and near the outer periphery of the current blocking portion 300. In particular, the peak of light emission intensity near the outer periphery of the current blocking portion 300 is higher than the peak of light emission intensity near the outer periphery of the upper electrode 40.

As described in the comparative example, the light emission intensity increases near the outer periphery of the upper electrode 40 and near the outer periphery of the current blocking portion 300. Taking this into consideration, the light emitting element 1 according to this embodiment is provided with protrusions 30a and depressions 30b at the periphery of the current blocking portion 30, for instance, to lengthen the perimeter of the current blocking portion 30, thereby further increasing the light emission intensity.

This phenomenon of increased light emission intensity by lengthening the perimeter of the current blocking portion 30 has been confirmed, for instance, by the following simulation.

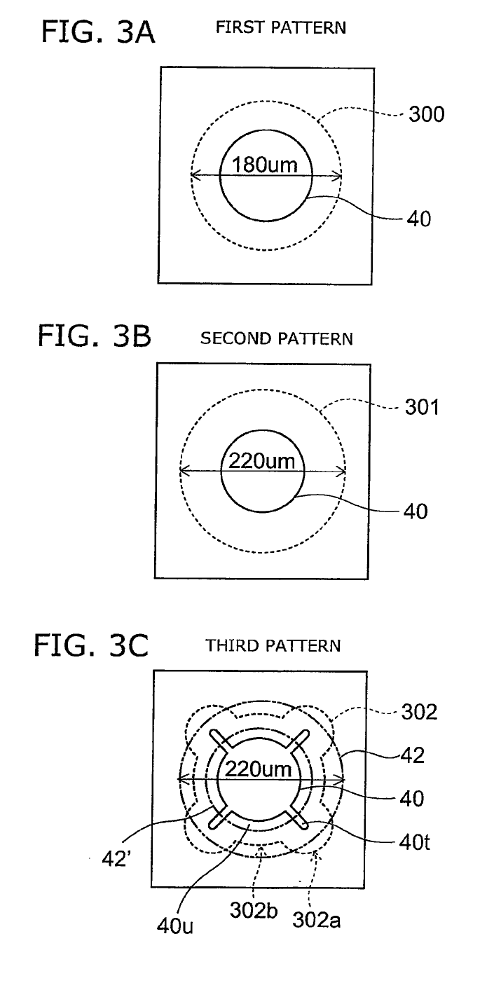

FIGS. 3A to 3C illustrate patterns of the current blocking portion. FIG. 3A shows a first pattern, FIG. 3B shows a second pattern, and FIG. 3C shows a third pattern. The first pattern corresponds to the planar pattern of the light emitting element 100 according to the comparative example.

The diameter of the current blocking portion 300 of the first pattern shown in FIG. 3A is 180 μm. The diameter of the current blocking portion 301 of the second pattern shown in FIG. 3B is 220 μm, which is larger than the diameter of the current blocking portion 300. The current blocking portion 302 of the third pattern shown in FIG. 3C is provided with a protrusion 302a and a depression 302b. The diameter of the similar shape 42 depicted in FIG. 3C is equal to the diameter of the current blocking portion 301 of the second pattern. In the third pattern, a protrusion 40t is provided in the upper electrode 40 so that the electrical resistance from the upper electrode 40 to the current blocking portion 302 is made more uniform. In other words, in the upper electrode 40 of the third pattern, a protrusion 40t is formed so as to be convex with respect to a similar shape 42′ of the basic outline of the upper electrode, and a depression 40u is formed so as to be concave with respect to the similar shape 42′ of the basic outline of the upper electrode. Furthermore, in the third pattern, as viewed in the direction perpendicular to the second major surface of the light emitting layer 22, the current blocking portion 302 has an outline spaced by a fixed distance outward from the periphery of the upper electrode 40 with the protrusion and depression formed with respect to the similar shape 42′ of the basic outline of the upper electrode.

The third pattern is formed as follows. An example process for forming the third pattern is described below in detail.

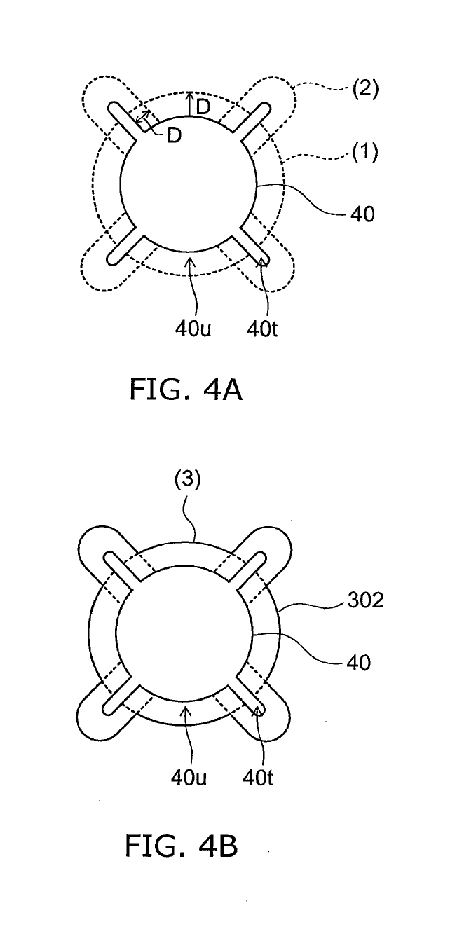

FIGS. 4A and 4B illustrate a process for forming the third pattern. FIG. 4A shows a first stage of pattern formation, and FIG. 4B shows a second stage of pattern formation.

For instance, as shown in FIG. 4A, a line is drawn at a fixed distance D outward from any position on the periphery of the upper electrode 40 with the aforementioned protrusion 40t and depression 40u formed with respect to the similar shape 42′ of the basic outline of the upper electrode. As shown, the line is composed of line (1) and line (2).

Next, as shown in FIG. 4B, the external contour of the figure composed of line (1) and line (2) is drawn. This external contour is defined as line (3). This line (3) is used as the outline of the current blocking portion 302. The third pattern like this is also encompassed in this embodiment.

That is, the perimeter of the current blocking portion lengthens with the transition from the current blocking portion 300 having the first pattern to the current blocking portion 302 having the third pattern.

Here, the third pattern is not limited to the shape of FIG. 3C. For instance, in the case where the upper electrode 40 having the basic outline includes a protrusion 40t, a virtual outline similar in shape to the basic outline may be used as the outline of the current blocking portion 302.

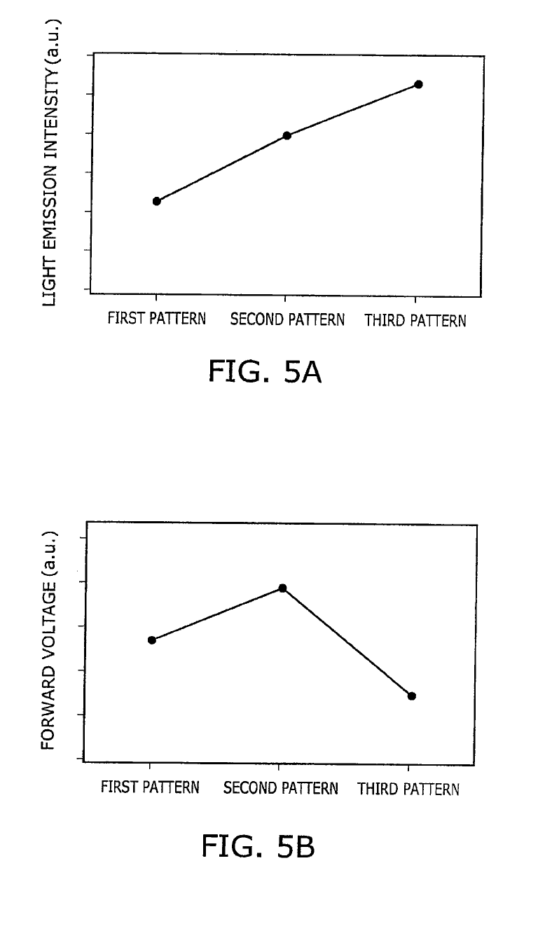

FIGS. 5A and 5B illustrate light emission intensity and forward voltage. FIG. 5A illustrates the relationship between the first to third pattern and light emission intensity. FIG. 5B illustrates the relationship between the first to third pattern and forward voltage.

As shown in FIG. 5A, the second pattern has higher light emission intensity than the first pattern. The third pattern has higher light emission intensity than the second pattern. As shown in FIG. 5B, the second pattern has higher forward voltage than the first pattern. However, the third pattern has lower forward voltage than the first and second pattern. That is, the light emission intensity increases as the perimeter of the current blocking portion 30 lengthens.

The reason for the increased light emission intensity is that the lengthened perimeter of the current blocking portion 30 extends (increases) the aforementioned current path region passing through the light emitting layer indicated by arrow B. However, if the perimeter of the current blocking portion 30 is made longer, the number of sites with a longer current flowing path indicated by arrow B increases, and the forward voltage tends to increase. In this case, the forward voltage can be reduced by providing a protrusion 40t in the upper electrode 40 to make the current path uniform.

In the light emitting element 1, the perimeter of the current blocking portion 30 is made longer so that the light emission intensity is made higher than in the light emitting element 100. That is, as shown in FIG. 1A, the current blocking portion 30 is provided with protrusions 30a projected outward from the center of the current blocking portion 30, and depressions 30b depressed from outside to inside. This increases the perimeter of the current blocking portion 30 of the light emitting element 1. Thus, the light emitting element 1 has higher light emission intensity than the light emitting element 100 according to the comparative example.

Here, the periphery of the current blocking portion 30 shown in FIG. 1A is an example of the fractal figure drawn with the Koch curve. The shapes of the current blocking portion illustrated below are also encompassed in the first embodiment.

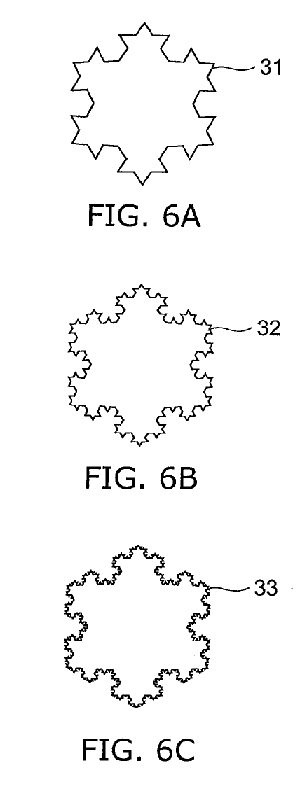

FIGS. 6A to 6C show variations of the current blocking portion according to the first embodiment. FIG. 6A is a plan view of the current blocking portion of a first variation. FIG. 6B is a plan view of the current blocking portion of a second variation. FIG. 6C is a plan view of the current blocking portion of a third variation.

In the current blocking portion 31 of the first variation shown in FIG. 6A, every side of the outer periphery of the current blocking portion 30 shown in FIG. 1A is divided into three segments of equal length. And the middle segment of this side is drawn as a new side of a regular triangle in the current blocking portion 31. Further application of this operation to the outer periphery of the current blocking portion 31 yields the current blocking portion 32 of the second variation shown in FIG. 6B. Further application of this operation to the outer periphery of the current blocking portion 32 yields the current blocking portion 33 of the third variation shown in FIG. 6C. Thus, as viewed in the direction perpendicular to the second major surface (upper surface side) of the light emitting layer 22, the periphery of the current blocking portion 31, 32, 33 has a configuration including the Koch curve. Furthermore, with the transition from FIG. 6A to FIG. 6C, the perimeter of the current blocking portion lengthens, and the light emission intensity increases. Here, the lower limit of one segment of the Koch curve is, for instance, the wavelength of light emitted from the light emitting element 1.

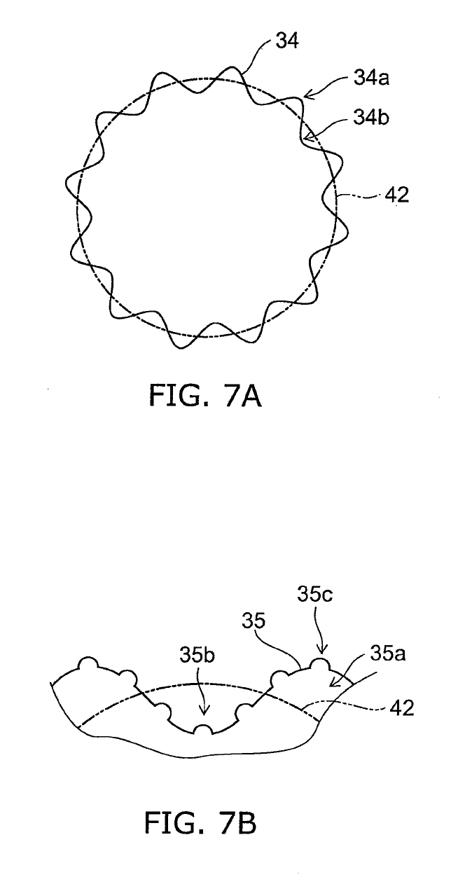

FIGS. 7A and 7B show other variations of the current blocking portion according to the first embodiment. FIG. 7A is a plan view of the current blocking portion of a fourth variation. FIG. 7B is a plan view of the current blocking portion of a fifth variation.

In the current blocking portion 34 of the fourth variation shown in FIG. 7A, as viewed in the direction perpendicular to the second major surface (upper surface side) of the light emitting layer 22, the periphery of the current blocking portion 34 is wavy. For instance, if a similar shape 42 to the upper electrode 40 is reference, the current blocking portion 34 includes a protrusion 34a projected outward from this reference, and a depression 34b depressed inward from this reference.

In the current blocking portion 35 of the fifth variation shown in FIG. 7B, the protrusion 35a and the depression 35b of the upper electrode 40 are provided with a protrusion 35c.

Also in such shapes, the perimeter of the current blocking portion lengthens, and the light emission intensity increases.

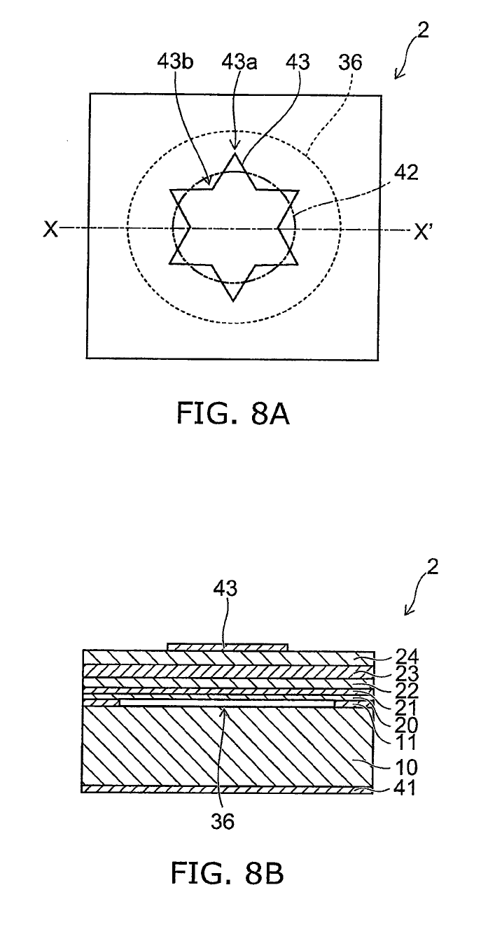

FIGS. 8A and 8B are schematic views of a relevant part of a light emitting element according to a second embodiment. FIG. 8A is a schematic plan view of the relevant part, and FIG. 8B is a schematic sectional view of the relevant part. FIG. 8B shows an X-X′ cross section of FIG. 8A.

In the light emitting element 2 according to the second embodiment as viewed in the direction perpendicular to the second major surface (upper surface side) of the light emitting layer 22, the periphery of the upper electrode 43 has a shape including a plurality of protrusions 43a directed from the center of the upper electrode 43 to outside, and a plurality of depressions 43b directed from outside to the center. That is, with reference to the similar shape 42 of the basic outline of the upper electrode 40 described above, the periphery of the upper electrode 43 itself has a protrusion-depression pattern with respect to the similar shape 42. The current blocking portion 36 has a circular shape.

Such a structure lengthens the aforementioned current path region passing through the light emitting layer indicated by arrow A. Thus, the light emission intensity is made higher than in the light emitting element 100.

The periphery of the upper electrode 43 is an example of the fractal figure drawn with the Koch curve, and may be shaped as shown in FIGS. 6A to 6C. Alternatively, the periphery of the upper electrode 43 may be shaped as shown in FIGS. 7A and 7B. This shape further increases the light emission intensity.

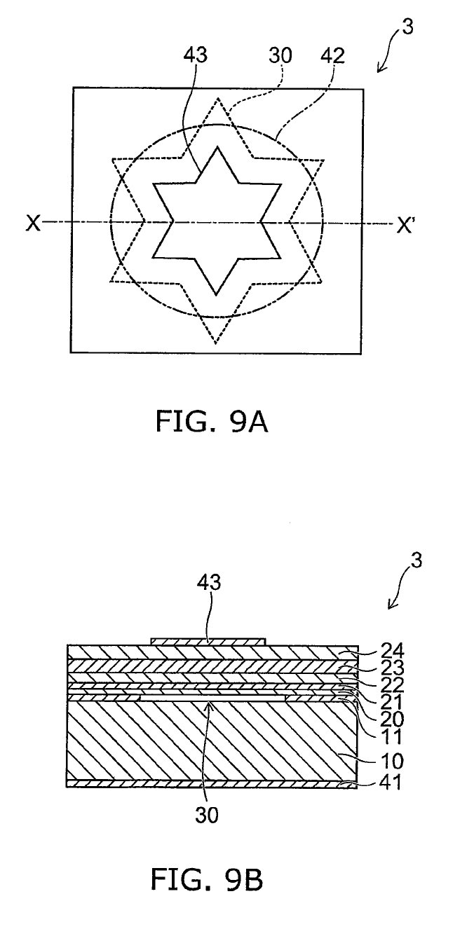

FIGS. 9A and 9B are schematic views of a relevant part of a light emitting element according to a third embodiment. FIG. 9A is a schematic plan view of the relevant part, and FIG. 9B is a schematic sectional view of the relevant part. FIG. 9B shows an X-X′ cross section of FIG. 9A.

As viewed in the direction perpendicular to the second major surface (upper surface side) of the light emitting layer 22, the light emitting element 3 according to the third embodiment includes a current blocking portion 30 and an upper electrode 43 similar in shape to this current blocking portion 30. That is, the upper electrode 43 has an outline having a protrusion-depression pattern with respect to the basic outline of the upper electrode 40, and is similar in shape to the current blocking portion 30. Thus, both the peripheries of the upper electrode 43 and the current blocking portion 30 have a protrusion-depression pattern.

Such a structure lengthens the aforementioned current path region passing through the light emitting layer indicated by arrow A and arrow B. Thus, the light emission intensity is made higher than in the light emitting elements 1, 2.

The periphery of the upper electrode 43 and the current blocking portion 30 of the light emitting element 3 may be shaped as shown in FIGS. 6A to 6C, or may be shaped as shown in FIGS. 7A and 7B. This shape further increases the light emission intensity. In particular, in the light emitting element 3, the upper electrode 43 and the current blocking portion 30 are similar in shape. Hence, the aforementioned current path indicated by arrow B is made more uniform, and the forward voltage can be reduced. This further improves the light emission efficiency of the light emitting element 3.

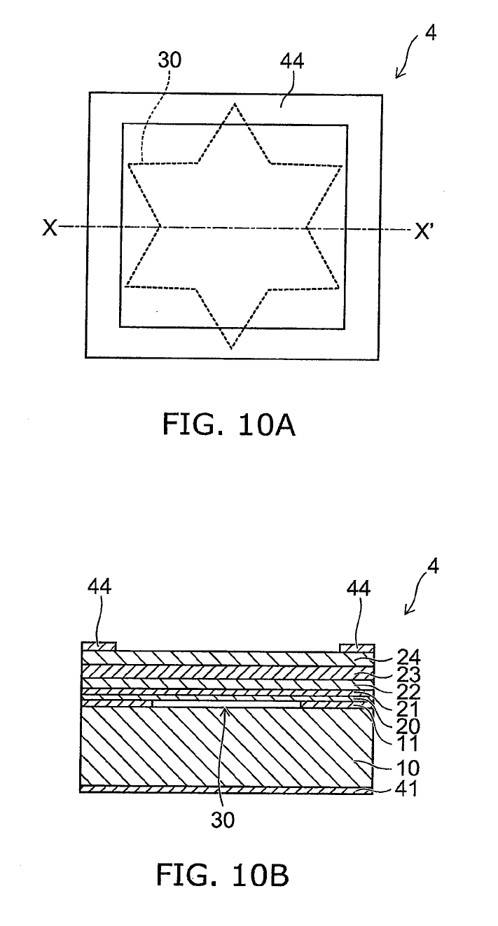

FIGS. 10A and 10B are schematic views of a relevant part of a light emitting element according to a fourth embodiment. FIG. 10A is a schematic plan view of the relevant part of the light emitting element, and FIG. 10B is a schematic sectional view of the relevant part.

As viewed from above, the light emitting element 4 according to the fourth embodiment includes a current blocking portion 30. Furthermore, an upper electrode 44 is provided like a ring shape above the outer periphery of the current diffusion layer 24. Such a structure lengthens the aforementioned current path region passing through the light emitting layer indicated by arrow A. Thus, the light emission intensity increases.

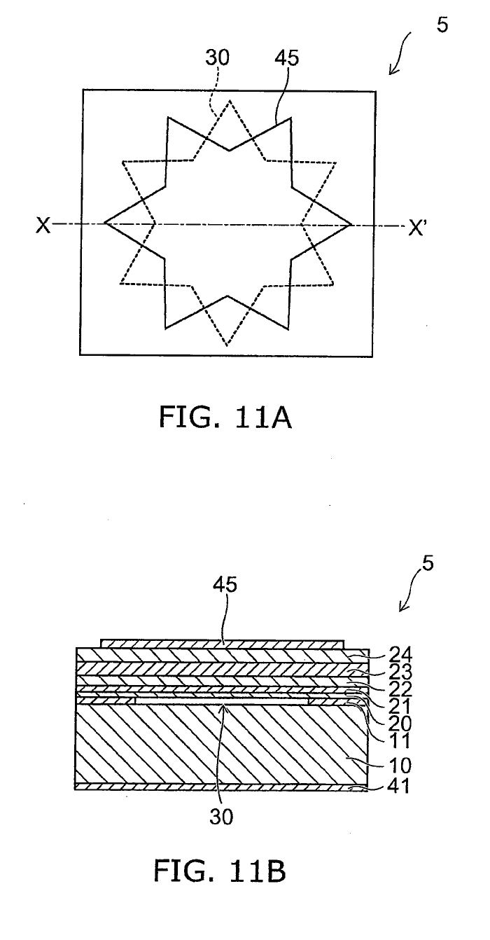

FIGS. 11A and 11B are schematic views of a relevant part of a light emitting element according to a fifth embodiment. FIG. 11A is a schematic plan view of the relevant part, and FIG. 11B is a schematic sectional view of the relevant part.

As viewed in the direction perpendicular to the second major surface (upper surface side) of the light emitting layer 22, the light emitting element 5 according to the fifth embodiment includes a current blocking portion 30 and an upper electrode 45 similar in shape to this current blocking portion 30. That is, both the peripheries of the upper electrode 45 and the current blocking portion 30 have a protrusion-depression pattern. The area of the upper electrode 45 is generally equal to the area of the current blocking portion 30. In the light emitting element 5, as viewed in the direction perpendicular to the major surface of the semiconductor layer 10, the current blocking portion 30 and the upper electrode 45 are displaced from each other so that the protrusion of the current blocking portion 30 does not overlap the protrusion of the upper electrode 45.

In such a structure, even if the area of the upper electrode 45 is generally equal to the area of the current blocking portion 30, the protrusion of the current blocking portion 30 and the protrusion of the upper electrode 45 do not overlap each other as viewed from above the light emitting element 5. Hence, the light emitted from the light emitting layer 22 can be efficiently extracted.

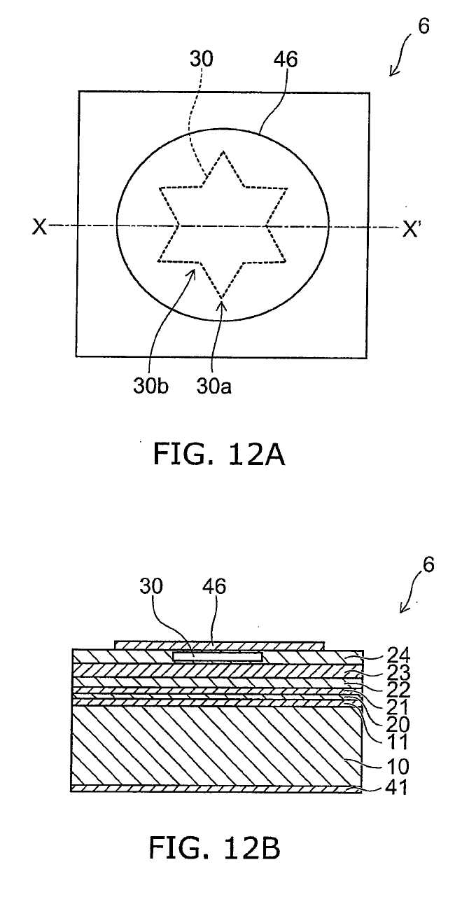

FIGS. 12A and 12B are schematic views of a relevant part of a light emitting element according to a sixth embodiment. FIG. 12A is a schematic plan view of the relevant part, and FIG. 12B is a schematic sectional view of the relevant part. FIG. 12B shows an X-X′ cross section of FIG. 12A.

The light emitting element 6 according to the sixth embodiment includes a current blocking portion 30 between the upper electrode 46 and the light emitting layer 22. The area of the upper electrode 46 is larger than the area of the current blocking portion 30.

As viewed in the direction perpendicular to the second major surface (upper surface side) of the light emitting layer 22, the current blocking portion 30 has a shape including a plurality of protrusions 30a with the periphery of the current blocking portion 30 directed from the center of the current blocking portion 30 to outside, and a plurality of depressions 30b with the periphery of the current blocking portion 30 directed from outside to the center. For instance, with reference to a similar shape 42 having a larger area than the upper electrode 40, the protrusion 30a is projected outward from this reference, and the depression 30b is depressed inward from this outer periphery.

Also in such a structure, the perimeter of the current blocking portion 30 lengthens, and the light emission intensity increases.

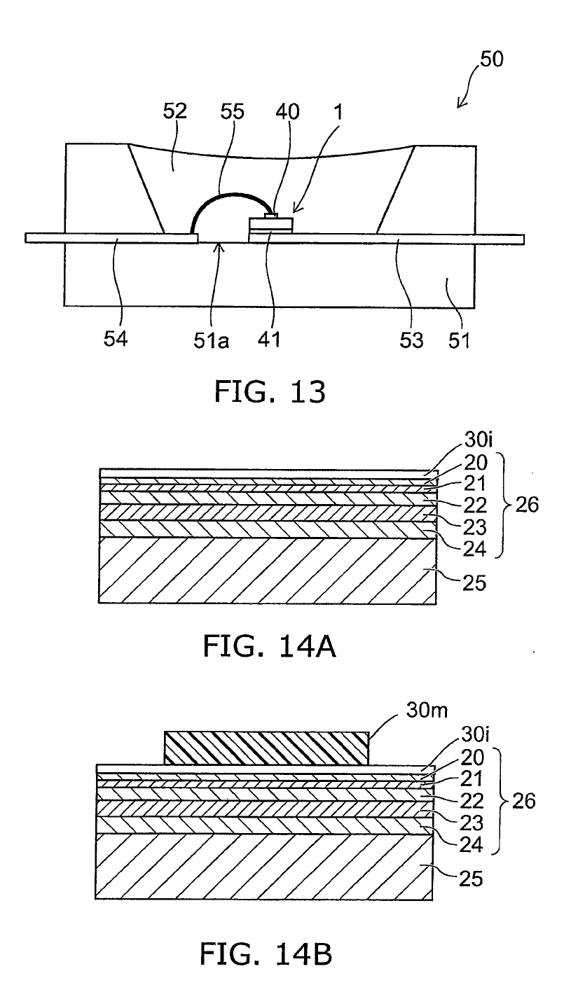

FIG. 13 is a schematic sectional view of a relevant part of a light emitting device according to a seventh embodiment.

The light emitting device 50 includes an enclosure 51 as a package member, a light emitting element 1 provided in the enclosure, and a resin layer 52 provided in the enclosure 51 so as to cover the light emitting element 1. The light emitting device 50 further includes a first lead frame 53 and a second lead frame 54. The lead frame 53 and the lead frame 54 are opposed to each other, and are each partly sealed in the enclosure 51. Part of the lead frame 53 and part of the lead frame 54 are exposed from the bottom surface 51a of the enclosure 51. The light emitting element 1 is mounted above the lead frame 53. The light emitting element mounted above the upper side of the lead frame 53 may be any of the light emitting elements 2-6 as well as the light emitting element 1.

The lower electrode 41 of the light emitting element 1 is electrically connected to the lead frame 53. The upper electrode 40 of the light emitting element 1 is electrically connected to the lead frame 54 by a bonding wire 55.

The outer ends of the lead frame 53, 54 protrude from the enclosure 51. When a voltage is applied to the protruding portions of the lead frame 53, 54, the upper electrode 40 and the lower electrode 41 of the light emitting element 1 can be applied with the voltage. Thus, light is emitted from the light emitting layer 22 of the light emitting element 1. The resin layer 52 is primarily composed of e.g. silicone resin. Fluorescent body may be contained in this resin layer 52. The fluorescent body receives the light emitted from the light emitting layer 22 and emits green or red light.

An example method for manufacturing the light emitting element of the present embodiments is described. The following description illustrates a method for manufacturing the light emitting element 1 including the current blocking portion 30 with the periphery drawn with the Koch curve. The current blocking portion 30 is illustratively an insulating layer

FIGS. 14A and 14B are schematic sectional views of the relevant part illustrating a process for manufacturing the light emitting element. FIG. 14A shows the step of forming a semiconductor stacked body, and FIG. 14B shows the step of forming a mask membrane.

First, as shown in FIG. 14A, the current diffusion layer 24, the second cladding layer 23, the light emitting layer 22, the first cladding layer 21, and the GaAs buffer layer 20 are sequentially stacked by epitaxial growth on the upper side of a GaAs substrate 25. Thus, a semiconductor stacked body 26 is formed in which the current diffusion layer 24, the cladding layer 23, the light emitting layer 22, the cladding layer 21, and the GaAs buffer layer 20 are sequentially stacked on the upper side of the GaAs substrate 25.

Subsequently, on the upper side of the GaAs buffer layer 20, an insulating film 30i is formed by the CVD (chemical vapor deposition) method. The material of the insulating film 30i is illustratively silicon oxide (SiO₂) or silicon nitride (Si₃N₄). The insulating film 30i is an insulation coating to be processed into a current blocking portion 30.

Next, as shown in FIG. 14B, a mask membrane 30m is selectively formed on the upper side of the insulating film 30i. The periphery of the mask membrane 30m is drawn with the Koch curve as viewed in the direction perpendicular to the major surface of the semiconductor stacked body 26. The mask membrane 30m is patterned by one-to-one projection or reduced projection exposure. The outline of the mask membrane 30m corresponds to the outline of the current blocking portion 30.

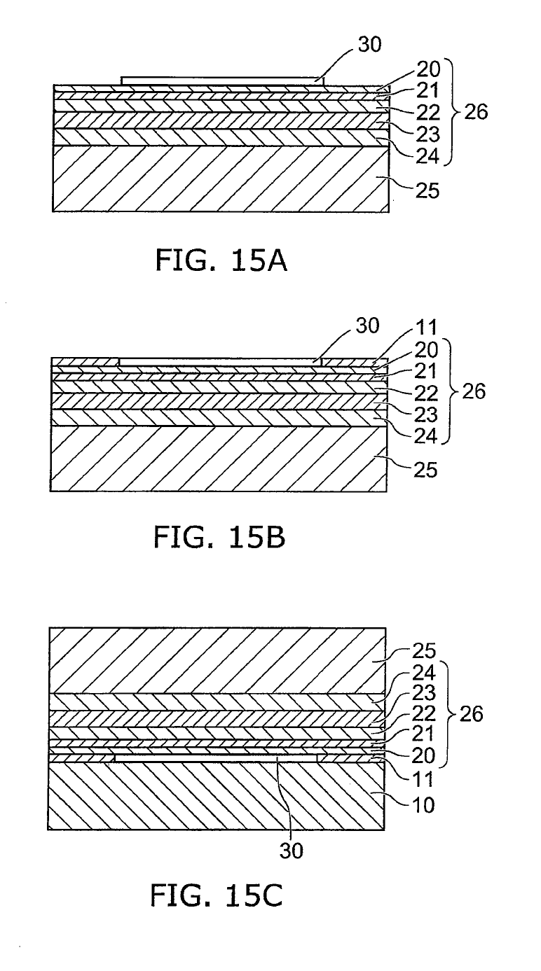

FIGS. 15A to 15C are schematic sectional views of the relevant part illustrating the process for manufacturing the light emitting element. FIG. 15A shows the step of forming a current blocking portion, FIG. 15B shows the step of forming a reflective film, and FIG. 15C shows the step of forming a semiconductor layer.

Next, as shown in FIG. 15A, the insulating film 30i exposed from the mask membrane 30m is removed by etching. Subsequently, the mask membrane 30m is removed. Thus, a current blocking portion 30 is formed on the upper side of the GaAs buffer layer 20.

That is, the current blocking portion 30 is formed on the upper side of the semiconductor stacked body 26. The current blocking portion 30 has the outline having the protrusion-depression pattern with respect to the virtual outline similar in shape to the basic outline of the upper electrode.

Next, as shown in FIG. 15B, the reflective film 11 is selectively formed on the upper side of the GaAs buffer layer 20 exposed from the current blocking portion 30. The reflective film 11 is a film based on gold (Au) or silver (Ag).

Next, as shown in FIG. 15C, the semiconductor stacked body 26 is turned upside down. Then, a semiconductor layer 10 is formed on the upper side of the reflective film 11. For instance, the reflective film 11 and the semiconductor layer 10 are laminated together. Thus, the reflective film 11 is bonded to the semiconductor layer 10.

After boding the reflective film 11 and the semiconductor layer 10, the GaAs substrate 25 is removed by etching.

Subsequently, as shown in FIGS. 1A and 1B, an upper electrode 40 is formed on the upper side of the current diffusion layer 24. Furthermore, a lower electrode 41 is formed on the lower side of the semiconductor layer 10.

By such a manufacturing process, the light emitting element 1 is formed.

Here, the current blocking portion formed in the process for manufacturing the light emitting element is not limited to the aforementioned current blocking portion 30. For instance, the current blocking portion 31 (FIG. 6A), the current blocking portion 32 (FIG. 6B), the current blocking portion 33 (FIG. 6C), the current blocking portion 34 (FIG. 7A), the current blocking portion 35 (FIG. 7B), the current blocking portion 36 (FIGS. 8A and 8B), and the current blocking portion 30 (FIGS. 9A and 9B, FIGS. 10A and 10B, FIGS. 11A and 11B, and FIGS. 12A and 12B) can also be manufactured by a similar manufacturing process. Furthermore, space may be formed as the current blocking portion.

The embodiments have been described above with reference to examples. However, the embodiments are not limited to these examples. That is, those skilled in the art can suitably modify these examples, and such modifications are also encompassed within the scope of the embodiments as long as they fall within the spirit of the invention. For instance, each component of the above examples and its layout, material, condition, shape, and size are not limited to those illustrated, but can be suitably modified.

At least two embodiments of the first to sixth embodiment can be combined with each other as long as technically feasible. Such combinations are also encompassed within the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A light emitting element comprising:
a light emitting layer having a first major surface and a second major surface;
a first electrode provided on the first major surface side of the light emitting layer;
a second electrode provided on the second major surface side of the light emitting layer and having a basic outline; and
a current blocking portion provided between the first electrode and the light emitting layer or between the second electrode and the light emitting layer and having an outline with a protrusion-depression pattern with respect to a virtual outline similar in shape to the basic outline of the second electrode.

2. The element according to claim 1, wherein the outline with the protrusion-depression pattern includes a Koch curve as viewed in a direction perpendicular to the second major surface of the light emitting layer.

3. The element according to claim 2, wherein lower limit of length of one segment of the Koch curve is wavelength of light emitted from the light emitting layer.

4. The element according to claim 1, wherein the outline with the protrusion-depression pattern is wavy as viewed in a direction perpendicular to the second major surface of the light emitting layer.

5. The element according to claim 4, wherein the wavy outline with the protrusion-depression pattern includes an additional protrusion.

6. The element according to claim 1, wherein if the basic outline of the second electrode includes a protrusion, the virtual outline similar in shape to the basic outline is the outline of the current blocking portion.

7. The element according to claim 1, wherein
the second electrode has an outline with a protrusion-depression pattern with respect to the basic outline, and
the second electrode and the current blocking portion are similar in shape.

8. The element according to claim 7, wherein as viewed in a direction perpendicular to the second major surface of the light emitting layer, area of the second electrode is equal to area of the current blocking portion.

9. The element according to claim 7, wherein as viewed in a direction perpendicular to the second major surface of the light emitting layer, the current blocking portion and the second electrode are displaced from each other, and
the protrusion of the second electrode and the protrusion of the current blocking portion do not overlap each other.

10. The element according to claim 1, wherein as viewed in a direction perpendicular to the second major surface of the light emitting layer, periphery of the current blocking portion includes a portion protruding outward from periphery of the second electrode.

11. The element according to claim 1, wherein as viewed in a direction perpendicular to the second major surface of the light emitting layer, area of the second electrode is larger than area of the current blocking portion.

12. A light emitting device comprising:
a light emitting element including a light emitting layer having a first major surface and a second major surface, a first electrode provided on the first major surface side of the light emitting layer, a second electrode provided on the second major surface side of the light emitting layer and having a basic outline, and a current blocking portion provided between the first electrode and the light emitting layer or between the second electrode and the light emitting layer and having an outline with a protrusion-depression pattern with respect to a virtual outline similar in shape to the basic outline of the second electrode;
a resin layer provided so as to cover the light emitting element;
a first lead frame electrically connected to the first electrode of the light emitting element; and
a second lead frame electrically connected to the second electrode of the light emitting element.

13. A method for manufacturing a light emitting element, comprising:
forming a semiconductor stacked body including a light emitting layer on upper side of a semiconductor substrate; and
forming a current blocking portion on upper side of the semiconductor stacked body, the current blocking portion having an outline with a protrusion-depression pattern with respect to a virtual outline similar in shape to a basic outline of an electrode provided on a second major surface side opposite to a first major surface side of the light emitting layer.

14. The method according to claim 13, wherein the outline with the protrusion-depression pattern includes a Koch curve as viewed in a direction perpendicular to a major surface of the semiconductor stacked body.

15. The method according to claim 13, wherein the outline with the protrusion-depression pattern is wavy as viewed in a direction perpendicular to a major surface of the semiconductor stacked body.

16. The method according to claim 13, wherein if the basic outline of the electrode includes a protrusion, the virtual outline similar in shape to the basic outline is the outline of the current blocking portion.

17. The method according to claim 13, wherein the electrode has an outline with a protrusion-depression pattern with respect to the basic outline, and
the second electrode and the current blocking portion are similar in shape.

18. The method according to claim 17, wherein as viewed in a direction perpendicular to the major surface of the semiconductor stacked body, area of the electrode is equal to area of the current blocking portion.

19. The method according to claim 17, wherein as viewed in a direction perpendicular to the major surface of the semiconductor stacked body, the current blocking portion and the electrode are displaced from each other, and
the protrusion of the electrode and the protrusion of the current blocking portion do not overlap each other.

20. The method according to claim 13, wherein as viewed in a direction perpendicular to a major surface of the semiconductor stacked body, periphery of the current blocking portion includes a portion protruding outward from periphery of the electrode.
